(19) United States
(12) Patent Application Publication
(10) Pub. No.: US 2026/0226320 A1
(43) Pub. Date: Aug. 6, 2026

(54) METHOD FOR PRODUCING SEMICONDUCTOR DEVICE AND LAMINATED BODY FOR TEMPORARY FIXING

(71) Applicant: Resonac Corporation, Minato-ku, Tokyo (JP)

(72) Inventors: Emi MIYAZAWA, Minato-ku, Tokyo (JP); Yuta AKASU, Minato-ku, Tokyo (JP); Shinya KAWASHITA, Minato-ku, Tokyo (JP); Tetsuya ENOMOTO, Minato-ku, Tokyo (JP); Takashi KAWAMORI, Minato-ku, Tokyo (JP)

(21) Appl. No.: 18/856,054

(22) PCT Filed: Jun. 10, 2024
(86) PCT No.: PCT/JP2024/021074

§ 371 Date: Oct. 11, 2024

(30) Foreign Application Priority Data
Jun. 15, 2023 (JP) 2023-098557

(51) Int. Cl. C09J 7/38; C09J 5/00; H10P 58/00

(52) U.S. Cl. CPC C09J 7/387; C09J 5/00; H10P 58/00; C09J 2203/326; C09J 2301/416

(57) ABSTRACT

A method for producing a semiconductor device includes preparing a laminated body including a support member, a light absorption layer, and a temporary fixing material layer containing a cured product of a thermosetting resin component from the support member and temporarily fixing the semiconductor member to the support member via the light absorption layer and the temporary fixing material layer. A push-in depth when on the surface of the temporary fixing material layer on a side where the semiconductor member is disposed, a nanoindentation method using a Berkovich indenter is performed under a condition of 25° C. such that a load is increased at a loading rate of 20 μN/second for 5 seconds, retained at 100 μN for 2 seconds after the load reaches 100 μN, and decreased at an unloading rate of 20 μN/second for 5 seconds until the load is 0 mN is 600 nm or more.

### TECHNICAL FIELD

The present disclosure relates to a method for producing a semiconductor device and a laminated body for temporary fixing.

### BACKGROUND ART

In the production of a semiconductor element, an integrated circuit is incorporated in a semiconductor substrate such as a semiconductor wafer and a semiconductor chip, and then, a semiconductor member including the semiconductor substrate may be processed. The semiconductor member, for example, is subjected to a processing treatment such as the grinding of the back surface and singulating using dicing. The semiconductor member, in general, is processed in the state of being temporarily fixed to a support member, and then, the semiconductor member is separated from the support member. For example, in Patent Literatures 1 and 2, a method for irradiating a temporary fixing material layer with light (laser light) to separate the semiconductor member from the support member is disclosed.

### CITATION LIST

### Patent Literature

Patent Literature 1: JP 2016-138182 A
Patent Literature 2: JP 2013-033814 A

### SUMMARY OF INVENTION

### Technical Problem

A main object of the present disclosure is to provide a method for producing a semiconductor device including processing a semiconductor member temporarily fixed to a support member, in which it is possible to sufficiently fix the semiconductor member and the support member.

### Solution to Problem

The present disclosure provides a method for producing a semiconductor device according to [1] to [5] and a laminated body for temporary fixing according to [6] to [10].
[1] A method for producing a semiconductor device, including:
   preparing a laminated body for temporary fixing including a support member, a light absorption layer, and a temporary fixing material layer containing a cured product of a thermosetting resin component in this order from the support member;
   temporarily fixing a semiconductor member to the support member via the light absorption layer and the temporary fixing material layer;
   processing the semiconductor member temporarily fixed to the support member; and
   irradiating the light absorption layer of the laminated body for temporary fixing with light from the support member side to separate the semiconductor member from the support member,
   in which a push-in depth when on a surface of the temporary fixing material layer on a side in which the semiconductor member is disposed, a nanoindentation method using a Berkovich indenter is performed under a condition of 25° C. such that a load is increased at a loading rate of 20 μN/second for 5 seconds, retained at 100 μN for 2 seconds after the load reaches 100 μN, and decreased at an unloading rate of 20 μN/second for 5 seconds until the load is 0 mN is 600 nm or more.
[2] The method for producing a semiconductor device according to [1],
   in which surface roughness in the surface of the temporary fixing material layer on a side in which the semiconductor member is disposed is 50 nm or less.
[3] The method for producing a semiconductor device according to [1] or [2],
   in which a surface tacky force at 30° C. in the surface of the temporary fixing material layer on a side in which the semiconductor member is disposed is 9.8×10⁻³ N or more.
[4] The method for producing a semiconductor device according to any of [1] to [3],
   in which the thermosetting resin component contains a thermoplastic resin and a thermosetting resin, and the thermoplastic resin contains a hydrocarbon resin.
[5] The method for producing a semiconductor device according to [4],
   in which the hydrocarbon resin contains a hydrocarbon resin having a monomer unit derived from styrene.
[6] A laminated body for temporary fixing used to temporarily fix a semiconductor member and a support member, including:
   a support member;
   a light absorption layer; and
   a temporary fixing material layer containing a cured product of a thermosetting resin component in this order from the support member,
   in which a push-in depth when on a surface of the temporary fixing material layer on a side in which the semiconductor member is disposed, a nanoindentation method using a Berkovich indenter is performed under a condition of 25° C. such that a load is increased at a loading rate of 20 μN/second for 5 seconds, retained at 100 μN for 2 seconds after the load reaches 100 μN, and decreased at an unloading rate of 20 μN/second for 5 seconds until the load is 0 mN is 600 nm or more.
[7] The laminated body for temporary fixing according to [6], in which surface roughness in the surface of the temporary fixing material layer on a side in which the semiconductor member is disposed is 50 nm or less.
[8] The laminated body for temporary fixing according to [6] or [7],
   in which a surface tacky force at 30° C. in the surface of the temporary fixing material layer on a side in which the semiconductor member is disposed is 9.8×10⁻³ N or more.
[9] The laminated body for temporary fixing according to any of [6] to [8],
   in which the thermosetting resin component contains a thermoplastic resin and a thermosetting resin, and
   the thermoplastic resin contains a hydrocarbon resin.
[10] The laminated body for temporary fixing according to [9],
   in which the hydrocarbon resin contains a hydrocarbon resin having a monomer unit derived from styrene.

### Advantageous Effects of Invention

According to the present disclosure, the method for producing a semiconductor device including processing the semiconductor member temporarily fixed to the support member is provided, in which it is possible to sufficiently fix the semiconductor member and the support member. In addition, in the method for producing a semiconductor device of several modes, there is a tendency that it is possible to sufficiently reduce a peeling residue after separating the semiconductor member from the support member. In addition, according to the present disclosure, the laminated body for temporary fixing used for such a method for producing a semiconductor device is provided.

### BRIEF DESCRIPTION OF DRAWINGS

FIG. 1 is a schematic cross-sectional view illustrating one embodiment of a laminated body for temporary fixing.

FIG. 2A and FIG. 2B are schematic cross-sectional views illustrating one embodiment of a method for producing a laminated body for temporary fixing.

FIG. 3A and FIG. 3B are schematic cross-sectional views illustrating one embodiment of a method for producing a semiconductor device.

FIG. 4A, FIG. 4B, and FIG. 4C are schematic cross-sectional views illustrating one embodiment of the method for producing a semiconductor device.

FIG. 5A and FIG. 5B are schematic cross-sectional views illustrating one embodiment of the method for producing a semiconductor device.

### DESCRIPTION OF EMBODIMENTS

Hereinafter, an embodiment of the present disclosure will be described suitably with reference to the drawings. However, the present disclosure is not limited to the following embodiment. In the following embodiment, constituents (also including steps and the like) thereof are not essential, unless otherwise specified. The sizes of the constituents in each of the drawings are conceptual, and a relative relationship of the size between the constituents is not limited to that illustrated in each of the drawings.

The same applies to numerical values and ranges thereof in the present disclosure, which does not limit the present disclosure. In this specification, a numerical range represented by using “to” includes numerical values described before and after “to” as the minimum value and the maximum value, respectively. In numerical ranges described in stages in this specification, the upper limit value or the lower limit value described in one numerical range may be replaced with the upper limit value or the lower limit value of a numerical range described in the other stage. In addition, in the numerical range described in this specification, the upper limit value or the lower limit value of the numerical range may be replaced with values described in Examples (Production Examples).

In this specification, the term “layer” includes not only a structure in which a layer is formed on the entire surface but also a structure in which a layer is formed on a part of the surface when observed as a plan view. In addition, in this specification, the term “step” includes not only an independent step but also a step that is not explicitly distinguishable from other steps insofar as a desired function of the step is attained.

In this specification, (meth)acrylate indicates acrylate or methacrylate corresponding thereto. The same also applies to other similar expressions such as a (meth)acryloyl group and a (meth)acrylic copolymer.

In this specification, only one type of materials exemplified below can be used alone, or two or more types thereof may be used in combination, in a range corresponding to a condition, unless otherwise specified. In a case where there are a plurality of substances corresponding to each component in a composition, the content of each component in the composition indicates the total amount of the plurality of substances in the composition, unless otherwise specified.

[Laminated body for Temporary Fixing and Method for Producing Same]

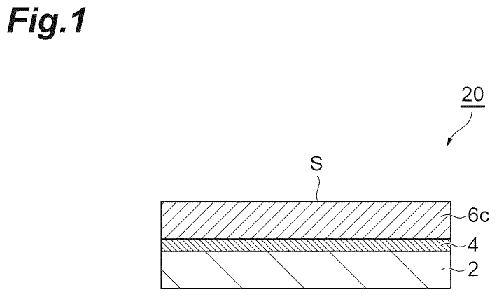

A laminated body for temporary fixing of this embodiment is used to temporarily fix a semiconductor member and a support member. FIG. 1 is a schematic cross-sectional view illustrating one embodiment of the laminated body for temporary fixing. A laminated body 20 for temporary fixing illustrated in FIG. 1 includes a support member 2, a light absorption layer 4, and a temporary fixing material layer 6c containing a cured product of a thermosetting resin component in this order from the support member 2. The temporary fixing material layer 6c has a surface S on a side of the temporary fixing material layer 6c where the semiconductor member is disposed (on a side opposite to the light absorption layer 4).

The support member 2 is a plate-shaped body that has a high transmittance and is capable of withstanding a load applied when processing the semiconductor member. Examples of the support member 2 include an inorganic glass substrate and a transparent resin substrate.

The thickness of the support member 2, for example, may be 0.1 to 2.0 mm. In a case where the thickness of the support member 2 is 0.1 mm or more, there is a tendency that easy handling is attained. In a case where the thickness of the support member 2 is 2.0 mm or less, there is a tendency that it is possible to suppress a material cost.

The light absorption layer 4 is a layer that absorbs light to generate heat. The light absorption layer 4, for example, may be a conductor layer containing a conductor that absorbs light to generate heat. Examples of the conductor configuring the conductor layer include a metal, a metal oxide, and a conductive carbon material. The metal may be a single metal such as chromium, copper, titanium, silver, platinum, and gold, or may be an alloy such as nickel-chromium, stainless steel, and copper-zinc. Examples of the metal oxide include indium tin oxide (ITO), zinc oxide, and niobium dioxide. The conductor may be chromium, titanium, or a conductive carbon material. The light absorption layer 4, for example, may be a conductor-containing resin layer containing a conductor that absorbs light to generate heat, and a resin.

The light absorption layer 4 may be a metal layer consisting of a single layer or a plurality of layers, and for example, may be a metal layer consisting of a copper layer and a titanium layer.

In a case where the light absorption layer 4 is a single metal layer, the light absorption layer 4 may contain at least one type of metal selected from the group consisting of tantalum (Ta), platinum (Pt), nickel (Ni), titanium (Ti), tungsten (W), chromium (Cr), copper (Cu), aluminum (Al), silver (Ag), and gold (Au).

The light absorption layer 4 is composed of two layers of a first layer and a second layer, in which the first layer and the second layer may be laminated in this order from the support member 2 side. In this case, for example, when the first layer has a high light absorption property, and the second layer has a high thermal expansion coefficient and a high elastic modulus, there is a tendency that it is easy to obtain excellent peelability. From such a viewpoint, the first layer of the light absorption layer 4 may contain at least one type of metal selected from the group consisting of tantalum (Ta), platinum (Pt), nickel (Ni), titanium (Ti), tungsten (W), and chromium (Cr), and the second layer of the light absorption layer 4 may contain at least one type of metal selected from the group consisting of copper (Cu), aluminum (Al), silver (Ag), and gold (Au).

The thickness of the light absorption layer 4, from the viewpoint of easy peelability, may be 1 to 5000 nm, 100 to 3000 nm, or 50 to 300 nm. In a case where the light absorption layer 4 is a metal layer consisting of a single layer or a plurality of layers, the thickness of the light absorption layer 4 (or the metal layer), from the viewpoint of excellent peelability, may be 75 nm or more, 90 nm or more, or 100 nm or more, 1000 nm or less, 800 nm or less, 500 nm or less, or 300 nm or less. In a case where the light absorption layer 4 is a single metal layer, the thickness of the light absorption layer 4 (or the metal layer), from the viewpoint of excellent peelability, may be 100 nm or more, 125 nm or more, 150 nm or more, or 200 nm or more, and may be 1000 nm or less, 800 nm or less, or 500 nm or less. In a case where the light absorption layer 4 is a conductor-containing resin layer, the thickness of the light absorption layer 4 may be 1 to 50 μm, may be 1 μm or more, 5 μm or more, or 10 μm or more, and may be 50 μm or less, 30 μm or less, or 20 μm or less.

A push-in depth when on the surface S of the temporary fixing material layer 6c, a nanoindentation method using a Berkovich indenter is performed under a condition of 25° C. such that a load is increased at a loading rate of 20 μN/second for 5 seconds, retained at 100 μN for 2 seconds after the load reaches 100 μN, and decreased at an unloading rate of 20 μN/second for 5 seconds until the load is 0 mN is 600 nm or more. In a case where the push-in depth is 600 nm or more, it is possible to sufficiently fix the semiconductor member and the support member via the light absorption layer and the temporary fixing material layer even after the thermosetting resin component is thermally cured. The push-in depth may be 650 nm or more, 700 nm or more, 750 nm or more, 800 nm or more, 850 nm or more, or 900 nm or more. The push-in depth, for example, may be 2000 nm or less, 1500 nm or less, or 1200 nm or less.

The push-in depth can be measured by performing a push-in test with a nanoindenter by a nanoindentation method using a Berkovich indenter, on the basis of ISO14577. More specifically, first, a thermosetting resin layer (a thermosetting resin film) with a thickness of 50 μm, which contains the thermosetting resin component, is prepared on a support film (the preparation of the thermosetting resin film will be described below). Next, the thermosetting resin layer (the thermosetting resin film) is stuck to a glass slide by using a roll laminator, and the support film is peeled to obtain a laminated body including the glass slide, and the thermosetting resin layer provided on the glass slide. In this case, the surface of the thermosetting resin layer that is in contact with the support film is a surface to be the surface S of the temporary fixing material layer 6c (the surface on a side where the semiconductor member is disposed). As the laminated body, a laminated body for temporary fixing described below may be used. Next, the prepared laminated body is heated in a drier in a condition of 200° C. for 1 hour to cure the thermosetting resin component of the thermosetting resin layer, and the temporary fixing material layer containing the cured product of the thermosetting resin component is formed to obtain a specimen. Subsequently, the obtained specimen is fixed to a stage of the nanoindenter, the Berkovich indenter is brought into contact with the surface of the temporary fixing material layer of the specimen, the push-in test is performed under a condition of 25° C. such that a load is increased at a loading rate of 20 μN/second for 5 seconds, retained at 100 μN for 2 seconds after the load reaches 100 μN, and decreased at an unloading rate of 20 μN/second for 5 seconds until the load is 0 mN, and a depth to which the Berkovich indenter is pushed into the temporary fixing material layer is measured by using the nanoindenter. The push-in test is performed at any 5 points, and among the obtained depths, the median value is set as the push-in depth.

### (Push-in Test Condition)

Indenter: a Berkovich indenter
Loading rate: 20 μN/second
Loading time: 5 seconds (Maximum Load: 100 μN)
Retention time: 2 seconds
Unloading rate: 20 μN/second

Surface roughness (arithmetic average roughness Ra (JIS B 0601-2001)) in the surface S may be 50 nm or less. In a case where the surface roughness is 50 nm or less, there is a tendency that it is possible to more sufficiently fix the semiconductor member and the support member via the light absorption layer and the temporary fixing material layer even after the thermosetting resin component is thermally cured. The surface roughness may be 40 nm or less, 30 nm or less, 25 nm or less, 20 nm or less, 15 nm or less, 10 nm or less, 8 nm or less, or 5 nm or less. The surface roughness, for example, may be 0.1 nm or more, or 1 nm or more.

The surface roughness can be obtained by preparing the same specimen as that in the push-in test, and measuring the surface of the temporary fixing material layer of the specimen with a stylus-type surface shape measuring system. A measurement condition is not particularly limited, and examples thereof include the following condition.

### (Measurement Condition)

Load: 4.9×10⁻⁶ N (5 mgf)
Movement rate: 0.3 mm/second
Measurement length: 30 mm

A surface tacky force at 30° C. in the surface S may be 9.8×10⁻³ N (1.0 gf) or more. In a case where the surface tacky force is 9.8×10⁻³ N (1.0 gf) or more, there is a tendency that it is possible to more sufficiently fix the semiconductor member and the support member via the light absorption layer and the temporary fixing material layer even after the thermosetting resin component is thermally cured. The surface tacky force may be 2.0×10⁻² N (2.0 gf) or more, 2.9×10⁻² N (3.0 gf) or more, 3.4×10⁻² N (3.5 gf) or more, 3.9×10⁻² N (4.0 gf) or more, 4.4×10⁻² N (4.5 gf) or more, or 4.9×10⁻² N (5.0 gf) or more. The surface tacky force, for example, may be 2.0×10⁻¹ N (20 gf) or less, 1.5×10⁻¹ N (15 gf) or less, or 9.8×10⁻² N (10 gf) or less.

For the surface tacky force, the same specimen as that in the push-in test is prepared, and the specimen is left to stand on a stage of a probe tackiness tester at 30° C. for 1 minute. Subsequently, the surface tacky force can be obtained by using the probe tackiness tester in the following measurement condition.

### (Measurement Condition)

Probe: stainless steel (SUS), a diameter of 5 mm
Push-in/peel rate: 600 mm/second
Push-in time: 1 second

The temporary fixing material layer 6c contains the cured product of the thermosetting resin component, and the thermosetting resin layer or the thermosetting resin film for forming the thermosetting resin layer contains the thermosetting resin component. The thermosetting resin component can be arbitrarily selected insofar as the push-in depth of the temporary fixing material layer containing the cured product of the thermosetting resin component satisfies a predetermined condition. The thermosetting resin component, for example, may be a thermoplastic resin and a thermosetting resin since there is a tendency that the push-in depth, the surface roughness, the surface tacky force, and the like easily satisfy a predetermined condition. In this case, the thermoplastic resin may contain a hydrocarbon resin. By the thermosetting resin component containing the thermoplastic resin and the thermosetting resin, there is a tendency that heat resistance is further improved compared to a case where the thermoplastic resin is used alone, and there is a tendency that a peeling residue can be sufficiently reduced compared to a case where the thermosetting resin is used alone.

The thermoplastic resin is a resin having a thermoplastic property, or a resin that has a thermoplastic property at least in an uncured state and forms a cross-linked structure after heating. Examples of the thermoplastic resin include a hydrocarbon resin, polycarbonate, polyphenylene sulfide, polyether sulfone, polyether imide, polyimide, a petroleum resin, and a novolac resin. The thermoplastic resin may contain the hydrocarbon resin, or may be the hydrocarbon resin.

The hydrocarbon resin is a resin of which the main skeleton is configured of hydrocarbon. Examples of such a hydrocarbon resin include an ethylene/propylene copolymer, an ethylene/1-butene copolymer, an ethylene/propylene/1-butene copolymer elastomer, an ethylene/1-hexene copolymer, an ethylene/1-octene copolymer, an ethylene/styrene copolymer, an ethylene/norbornene copolymer, a propylene/1-butene copolymer, an ethylene/propylene/non-conjugated diene copolymer, an ethylene/1-butene/non-conjugated diene copolymer, an ethylene/propylene/1-butene/non-conjugated diene copolymer, polyisoprene, polybutadiene, a styrene/butadiene/styrene block copolymer (SBS), a styrene/isoprene/styrene block copolymer (SIS), a styrene/ethylene/butylene/styrene block copolymer (SEBS), and a styrene/ethylene/propylene/styrene block copolymer (SEPS). Such hydrocarbon resins may be subjected to a hydrogenation treatment. In addition, such hydrocarbon resins may be carboxy-modified with a maleic anhydride or the like. Among them, the hydrocarbon resin may contain a hydrocarbon resin having a monomer unit derived from styrene (that is, a styrene-based resin), or may be the styrene-based resin. More specifically, the hydrocarbon resin may contain the styrene/ethylene/butylene/styrene block copolymer (SEBS), or may be the styrene/ethylene/butylene/styrene block copolymer (SEBS).

The content of the hydrocarbon resin (or the styrene-based resin) may be 50% by mass or more, 70% by mass or more, or 90% by mass or more, on the basis of the total amount of the thermoplastic resin. The content of the hydrocarbon resin (or the styrene-based resin) may be 100% by mass or less, on the basis of the total amount of the thermoplastic resin. In a case where the content of the hydrocarbon resin (or the styrene-based resin) is in such a range, there is a tendency that it is easy to adjust the storage elastic modulus of the thermosetting resin film to a desired range, and there is a tendency that the effect of the present disclosure is remarkably exhibited. The thermoplastic resin may be composed of the hydrocarbon resin (or the styrene-based resin).

The content of the styrene-based resin (or SEBS) may be 50% by mass or more, 70% by mass or more, or 90% by mass or more, on the basis of the total amount of the hydrocarbon resin. The content of the styrene-based resin (or SEBS) may be 100% by mass or less, on the basis of the total amount of the hydrocarbon resin. In a case where the content of the styrene-based resin (or SEBS) is in such a range, there is a tendency that it is easy to adjust the storage elastic modulus of the thermosetting resin film to a desired range, and there is a tendency that the effect of the present disclosure is remarkably exhibited. The hydrocarbon resin may be composed of the styrene-based resin (or SEBS).

In a case where the hydrocarbon resin contains the styrene-based resin, the content of the monomer unit derived from styrene may be 10 to 22.5% by mass, on the basis of the total amount of the hydrocarbon resin (or the thermoplastic resin). In a case where the content of the monomer unit derived from styrene is in such a range, there is a tendency that it is easy to adjust the storage elastic modulus of the thermosetting resin film to a desired range, and there is a tendency that the effect of the present disclosure is remarkably exhibited. Note that in the case of using two or more types of styrene-based resins in combination, the content of the monomer unit derived from styrene indicates the total content of the monomer unit derived from styrene in two or more types of styrene-based resins. The content of the monomer unit derived from styrene may be 11% by mass or more, 12% by mass or more, or 13% by mass or more, and may be 22% by mass or less, or 21.5% by mass or less, on the basis of the total amount of the hydrocarbon resin (or the thermoplastic resin).

In a case where the thermosetting resin component contains the styrene-based resin as the thermoplastic resin (the hydrocarbon resin), the content of the monomer unit derived from styrene may be 7 to 16% by mass, on the basis of the total amount of the thermosetting resin component. In a case where the content of the monomer unit derived from styrene is in such a range, there is a tendency that it is easy to adjust the storage elastic modulus of the thermosetting resin film to a desired range, and there is a tendency that the effect of the present disclosure is remarkably exhibited. Note that in the case of using two or more types of styrene-based resins in combination, the content of the monomer unit derived from styrene indicates the total content of the monomer unit derived from styrene in two or more types of styrene-based resins. The content of the monomer unit derived from styrene may be 7.5% by mass or more, 8% by mass or more, or 9% by mass or more, and may be 15.5% by mass or less, or 15% by mass or less, on the basis of the total amount of the thermosetting resin component.

Tg of the thermoplastic resin may be −100 to 500° C., −50 to 300° C., or −50 to 50° C. In a case where Tg of the thermoplastic resin is 500° C. or lower, there is a tendency that it is easy to ensure ductility, and it is possible to improve a low-temperature sticking property when forming a film-shaped temporary fixing material. In a case where Tg of the thermoplastic resin is −100° C. or higher, there is a tendency that it is possible to suppress a decrease in handleability and the peelability due to an excessive increase in the ductility when forming the film-shaped temporary fixing material.

Tg of the thermoplastic resin is an intermediate glass transition temperature obtained by differential scanning calorimetry (DSC). Specifically, Tg of the thermoplastic resin is an intermediate glass transition temperature calculated by measuring a caloric change in a condition of a temperature increase rate of 10° C./minute and a measurement temperature of −80 to 80° C. using a method based on JIS K7121:2012.

The weight average molecular weight (Mw) of the thermoplastic resin may be 10000 to 5000000, or 100000 to 2000000. In a case where the weight average molecular weight is 10000 or more, there is a tendency that it is easy to ensure the heat resistance of the temporary fixing material layer to be formed. In a case where the weight average molecular weight is 5000000 or less, there is a tendency that it is easy to suppress a decrease in a flow and a decrease in a sticking property when forming the thermosetting resin film. Note that the weight average molecular weight is a value in terms of polystyrene using a calibration curve of standard polystyrene by gel permeation chromatography (GPC).

The content of the thermoplastic resin, for example, may be 40 to 90% by mass, on the basis of the total amount of the thermosetting resin component. The content of the thermoplastic resin, for example, may be 50% by mass or more, or 60% by mass or more, and may be 85% by mass or less, or 80% by mass or less, on the basis of the total amount of the thermosetting resin component. In a case where the content of the thermoplastic resin is in such a range, there is a tendency that it is more excellent in the thin film formability and the flatness of the temporary fixing material layer.

The thermosetting resin is a resin exhibiting curability by heat, and is a concept not including the thermoplastic resin (the hydrocarbon resin) described above. Examples of the thermosetting resin include an epoxy resin, an acrylic resin, a silicone resin, a phenol resin, a thermosetting polyimide resin, a polyurethane resin, a melamine resin, and a urea resin. Among them, the thermosetting resin, from the viewpoint of being more excellent in the heat resistance, workability, and reliability, may be the epoxy resin.

The epoxy resin is not particularly limited insofar as the epoxy resin has a heat resistance function by curing. Examples of the epoxy resin include a divalent epoxy resin such as bisphenol A-type epoxy, a novolac-type epoxy resin such as a phenol novolac-type epoxy resin and a cresol novolac-type epoxy resin, and an alicyclic epoxy resin such as a dicyclopentadiene-type epoxy resin. In addition, the epoxy resin, for example, may be a polyfunctional epoxy resin, a glycidyl amine-type epoxy resin, or a heterocyclic ring-containing epoxy resin. Among them, the epoxy resin, from the viewpoint of the heat resistance and weather resistance, may be the alicyclic epoxy resin.

In a case where the epoxy resin is used as the thermosetting resin, the thermosetting resin may be a combination of the epoxy resin and an epoxy resin curing agent. As the epoxy resin curing agent, it is possible to use a known curing agent that is commonly used. Examples of the epoxy resin curing agent include amine, polyamide, an acid anhydride, polysulfide, boron trifluoride, bisphenol (such as bisphenol A, bisphenol F, and bisphenol S), and a phenol resin (such as a phenol novolac resin, a bisphenol A-type novolac resin, a cresol novolac resin, and a phenol aralkyl resin).

The content of the thermosetting resin, for example, may be 10 to 60% by mass, on the basis of the total amount of the thermosetting resin component. The content of the thermosetting resin, for example, may be 15% by mass or more, or 20% by mass or more, and may be 50% by mass or less, or 40% by mass or less, on the basis of the total amount of the thermosetting resin component. In a case where the content of the thermosetting resin is in such a range, there is a tendency that it is more excellent in the thin film formability and the flatness of the temporary fixing material layer.

The thermosetting resin component may further contain a curing accelerator for accelerating a curing reaction of the thermosetting resin such as an epoxy resin. Examples of the curing accelerator include an imidazole derivative, a dicyan diamide derivative, dicarboxylic acid dihydrazide, triphenyl phosphine, tetraphenyl phosphonium tetraphenyl borate, 2-ethyl-4-methyl imidazole-tetraphenyl borate, and 1,8-diazabicyclo [5,4,0]undecene-7-tetraphenyl borate.

The content of the curing accelerator may be 0.01 to 5% by mass, on the basis of the total amount of the thermosetting resin. In a case where the content of the curing accelerator is in such a range, there is a tendency that the curability and the heat resistance after curing of the thermosetting resin component are more excellent. The content of the curing accelerator, from the viewpoint of easily adjusting a storage elastic modulus at 270° C. and a storage elastic modulus at 25° C. to a predetermined range, may be 1.0% by mass or more, 1.2% by mass or more, or 1.5% by mass or more, and may be 3.0% by mass or less, 2.5% by mass or less, or 2.0% by mass or less, on the basis of the total amount of the thermosetting resin.

The thermosetting resin component may further contain a polymerizable monomer and a polymerization initiator. The polymerizable monomer is not particularly limited insofar as the polymerizable monomer is polymerized by heating or the irradiation of an ultraviolet ray or the like. The polymerizable monomer, from the viewpoint of the selectivity and the availability of a material, for example, may be a compound having a polymerizable functional group such as an ethylenically unsaturated group. Examples of the polymerizable monomer include (meth)acrylate, halogenated vinylidene, vinyl ether, vinyl ester, vinyl pyridine, vinyl amide, and arylated vinyl. Among them, the polymerizable monomer may be the (meth)acrylate. The (meth)acrylate may be monofunctional, difunctional, or tri- or higher functional (meth)acrylate, and from the viewpoint of obtaining sufficient curability, may be di- or higher functional (meth)acrylate.

The content of the polymerizable monomer may be 0 to 50% by mass, on the basis of the total amount of the thermosetting resin component.

The polymerization initiator is not particularly limited insofar as the polymerization initiator initiates polymerization by heating or the irradiation of an ultraviolet ray or the like. For example, in a case where the compound having an ethylenically unsaturated group is used as the polymerizable monomer, the polymerizable initiator may be a thermal radical polymerization initiator or a photoradical polymerization initiator.

The content of the polymerization initiator may be 0.01 to 5% by mass, on the basis of the total amount of the polymerizable monomer.

The thermosetting resin component can be the main component of the thermosetting resin layer (the thermosetting resin film). The content of the thermosetting resin component may be 70% by mass or more, 80% by mass or more, 90% by mass or more, 95% by mass or more, or 98% by mass or more, on the basis of the total amount of the thermosetting resin layer (the thermosetting resin film).

The thermosetting resin layer (the thermosetting resin film) may contain other components, in addition to the thermosetting resin component. Examples of the other component include an insulating filler, a sensitizer, and an antioxidant.

The insulating filler can be added in order to impart low thermal expansibility, low hygroscopicity, or the like to the temporary fixing material layer. Examples of the insulating filler include a non-metal inorganic filler such as silica, alumina, boron nitride, titania, glass, and ceramic. The insulating filler, from the viewpoint of dispersibility in a solvent, may be particles of which the surfaces are treated with a surface treatment agent. The surface treatment agent, for example, may be a silane coupling agent.

The content of the insulating filler may be 0.1 to 20% by mass, on the basis of the total amount of the thermosetting resin component. In a case where the content of the insulating filler is in such a range, there is a tendency that it is possible to further improve the heat resistance without hindering light transmission. In addition, in a case where the content of the insulating filler is in such a range, it may also contribute to easy peelability.

Examples of the sensitizer include anthracene, phenanthrene, chrysene, benzopyrene, fluoranthene, rubrene, pyrene, xanthone, indanthrene, thioxanthen-9-one, 2-isopropyl-9H-thioxanthen-9-one, 4-isopropyl-9H-thioxanthen-9-one, and 1-chloro-4-propoxythioxanthone.

The content of the sensitizer may be 0.01 to 10% by mass, on the basis of the total amount of the thermosetting resin component. In a case where the content of the sensitizer is in such a range, there is a tendency that the property and the thin film property of the thermosetting resin component are less affected.

Examples of the antioxidant include a quinone derivative such as benzoquinone and hydroquinone, a phenol derivative (a hindered phenol derivative) such as 4-methoxyphenol and 4-t-butyl catechol, an aminoxyl derivative such as 2,2,6,6-tetramethyl piperidine-1-oxyl and 4-hydroxy-2,2,6,6-tetramethyl piperidine-1-oxyl, and a hindered amine derivative such as tetramethyl piperidyl methacrylate.

The content of the antioxidant may be 0.1 to 10% by mass, on the basis of the total amount of the thermosetting resin component. In a case where the content of the antioxidant is in such a range, there is a tendency that it is possible to suppress the decomposition of the thermosetting resin component, and prevent contamination.

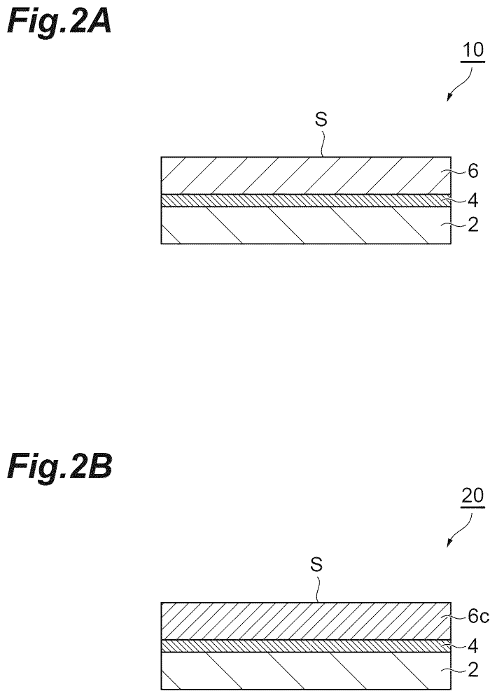

FIG. 2A and FIG. 2B are schematic cross-sectional views illustrating one embodiment of a method for producing a laminated body for temporary fixing. The laminated body 20 for temporary fixing, for example, can be obtained by a method including preparing a laminated precursor 10 including the support member 2, the light absorption layer 4, and a thermosetting resin layer 6 containing the thermosetting resin component in this order from the support member 2, and heating the laminated precursor 10 to form the temporary fixing material layer 6c containing the cured product of the thermosetting resin component.

The laminated precursor 10, for example, can be obtained by a method including providing the light absorption layer 4 on the support member 2, and sticking the thermosetting resin film containing the thermosetting resin component onto the light absorption layer 4 to form the thermosetting resin layer 6.

The light absorption layer 4 can be provided on the support member 2 by performing physical vapor deposition (PVD) such as vacuum vapor deposition and sputtering, chemical vapor deposition (CVD) such as plasma chemical vapor deposition, and the like. In addition, the light absorption layer 4 can be provided on the support member 2 by performing electrolytic plating or electroless plating. According to the physical vapor deposition, even in a case where the support member 2 has a large area, it is possible to efficiently form the light absorption layer 4 covering the surface of the support member 2.

For the thermosetting resin film for forming the thermosetting resin layer 6, for example, first, components configuring the thermosetting resin component are dissolved or dispersed in a solvent by stirring, mixing, kneading, or the like to prepare a varnish of the thermosetting resin component. After that, the varnish of the thermosetting resin component is applied onto the support film subjected to a mold release treatment with a knife coater, a roll coater, an applicator, a comma coater, a die coater, or the like, and then, the solvent is volatilized by heating to form the thermosetting resin film consisting of the thermosetting resin component on the support film. In this case, by adjusting the applied amount of the varnish of the thermosetting resin component, it is possible to adjust the thickness of the thermosetting resin film.

The solvent used to prepare the varnish of the thermosetting resin component is not particularly limited insofar as the solvent has a property capable of homogeneously dissolving or dispersing each of the components. Examples of such a solvent include aromatic hydrocarbon such as toluene, xylene, mesitylene, cumene, and p-cymene; aliphatic hydrocarbon such as hexane and heptane; cyclic alkane such as methyl cyclohexane; cyclic ether such as tetrahydrofuran and 1,4-dioxane; ketone such as acetone, methyl ethyl ketone, methyl isobutyl ketone, cyclohexanone, and 4-hydroxy-4-methyl-2-pentanone; ester such as methyl acetate, ethyl acetate, butyl acetate, methyl lactate, ethyl lactate, and γ-butyrolactone; carbonic acid ester such as ethylene carbonate and propylene carbonate; and amide such as N,N-dimethyl formamide, N,N-dimethyl acetamide, and N-methyl-2-pyrrolidone. Among them, the solvent, from the viewpoint of solubility and a boiling point, may be the toluene, the xylene, the heptane, or the cyclohexanone. A solid content concentration in the varnish may be 10 to 80% by mass, on the basis of the total amount of the varnish.

The stirring, mixing, or kneading when preparing the varnish of the thermosetting resin component, for example, can be performed by using a stirrer, a mortar machine, a three-roll mill, a ball mill, a beads mill, a homodisperser, or the like.

Examples of the support film include films of polyester such as polyethylene terephthalate (PET), polybutylene terephthalate, and polyethylene naphthalate; polyolefin such as polyethylene and polypropylene; such as polycarbonate, polyamide, polyimide, polyamide imide, polyether imide, polyether sulfide, polyether sulfone, polyether ketone, polyphenylene ether, polyphenylene sulfide, poly(meth)acrylate, polysulfone, and a liquid crystal polymer. The thickness of the support film, for example, may be 1 to 250 μm. A heating condition when volatilizing the solvent from the varnish of the thermosetting resin component applied to the support film can be suitably set in accordance with the solvent used, or the like. The heating condition, for example, may be at 40 to 120° C. for 0.1 to 30 minutes.

Examples of a method for sticking the thermosetting resin film onto the light absorption layer 4 include a method such as roll lamination, vacuum lamination, and heating press. The lamination, for example, can be performed under a temperature condition of 0 to 120° C.

The thickness of the thermosetting resin layer 6 (the thermosetting resin film), from the viewpoint of stress relaxation, for example, may be 0.1 μm or more, 1 μm or more, or 5 μm or more, and may be 200 μm or less, 100 μm or less, or 70 μm or less.

Subsequently, the thermosetting resin component of the thermosetting resin layer 6 in the obtained laminated precursor 10 is thermally cured to form the temporary fixing material layer 6c containing the cured product of the thermosetting resin component. A thermal curing condition, for example, may be at 150 to 300° C. or lower or 180 to 250° C., for 1 to 180 minutes or 10 to 120 minutes.

The thickness of the temporary fixing material layer 6c, from the viewpoint of the stress relaxation, for example, may be 0.1 μm or more, 1 μm or more, or 5 μm or more, and may be 200 μm or less, 100 μm or less, or 70 μm or less.

As described above, the laminated body 20 for temporary fixing can be obtained from the laminated precursor 10.

### [Method for Producing Semiconductor Device]

A method for producing a semiconductor device of this embodiment includes preparing the laminated body for temporary fixing (a preparing step), temporarily fixing the semiconductor member to the support member via the light absorption layer and the temporary fixing material layer (a temporarily fixing step), processing the semiconductor member temporarily fixed to the support member (a processing step), and irradiating the light absorption layer of the laminated body for temporary fixing with light from the support member side to separate the semiconductor member from the support member (a separating step). According to the method for producing a semiconductor device of this embodiment, since the laminated body for temporary fixing is used, it is possible to sufficiently fix the semiconductor member and the support member, and easily separate the processed semiconductor member from the support member while suppressing the occurrence of a residue.

### (Preparing Step)

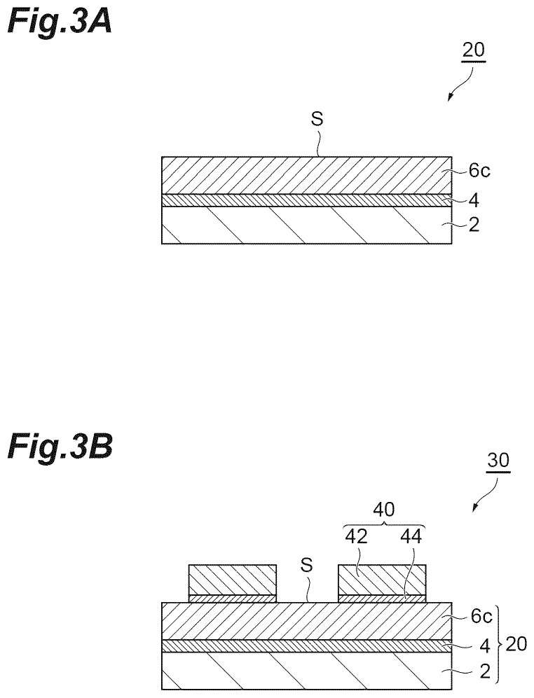

FIG. 3A and FIG. 3B are schematic cross-sectional views illustrating one embodiment of the method for producing a semiconductor device. In the preparing step, in order to produce the semiconductor device, the laminated body 20 for temporary fixing for temporarily fixing the semiconductor member to the support member while processing the semiconductor member is prepared (refer to FIG. 3A).

### (Temporarily Fixing Step)

In the temporarily fixing step, a semiconductor member 40 is temporarily fixed to the support member 2 via the light absorption layer 4 and the temporary fixing material layer 6c. The temporary fixing material layer 6c has the surface S of the temporary fixing material layer 6c on a side opposite to the light absorption layer 4. In the temporarily fixing step, for example, by crimping the semiconductor member 40 in a state where the semiconductor member 40 is disposed on the temporary fixing material layer 6c (refer to FIG. 3B), it is possible to temporarily fix the semiconductor member 40 to the support member 2 (refer to FIG. 3B). In other words, the semiconductor member 40 may temporarily adhere to the support member 2 via the light absorption layer 4 and the temporary fixing material layer 6c containing the cured product of the thermosetting resin component. As described above, a laminated body 30 including the laminated body 20 for temporary fixing, and the semiconductor member 40 provided on the temporary fixing material layer 6c of the laminated body 20 for temporary fixing is formed.

Examples of the semiconductor member 40 include a semiconductor member having a semiconductor substrate 42 and a redistribution layer 44. In a case where the semiconductor member 40 has the semiconductor substrate 42 and the redistribution layer 44, the semiconductor member 40 is temporarily fixed to the support member 2 via the light absorption layer 4 and the temporary fixing material layer 6c in a direction where the redistribution layer 44 is positioned on the temporary fixing material layer 6c side. The semiconductor member 40 may further have an external connecting terminal. The semiconductor substrate 42 may be a semiconductor wafer, or a semiconductor chip obtained by dividing the semiconductor wafer. In the example of FIG. 3A, a plurality of semiconductor members 40 are disposed on the surface S of the temporary fixing material layer 6c, but the number of semiconductor members 40 may be 1. The thickness of the semiconductor member 40, from the viewpoint of suppressing a crack during transport, the processing step, or the like, in addition to downsizing and thinning the semiconductor device, may be 1 to 1000 μm, 10 to 500 μm, or 20 to 200 μm.

The semiconductor member 40 disposed on the temporary fixing material layer 6c, for example, is crimped to the temporary fixing material layer 6c by a vacuum presser or a vacuum laminator. In the case of using the vacuum presser, a crimping condition may be an atmospheric pressure of 1 hPa or less, a crimping pressure of 1 MPa, a crimping temperature of 120 to 200° C., and a retention time of 100 to 300 seconds. In the case of using the vacuum laminator, a crimping condition, for example, may be an atmospheric pressure of 1 hPa or less, a crimping temperature of 60 to 180° C. or 80 to 150° C., a laminating pressure of 0.01 to 1.0 MPa or 0.1 to 0.7 MPa, and a retention time of 1 to 600 seconds or 30 to 300 seconds.

### (Processing Step)

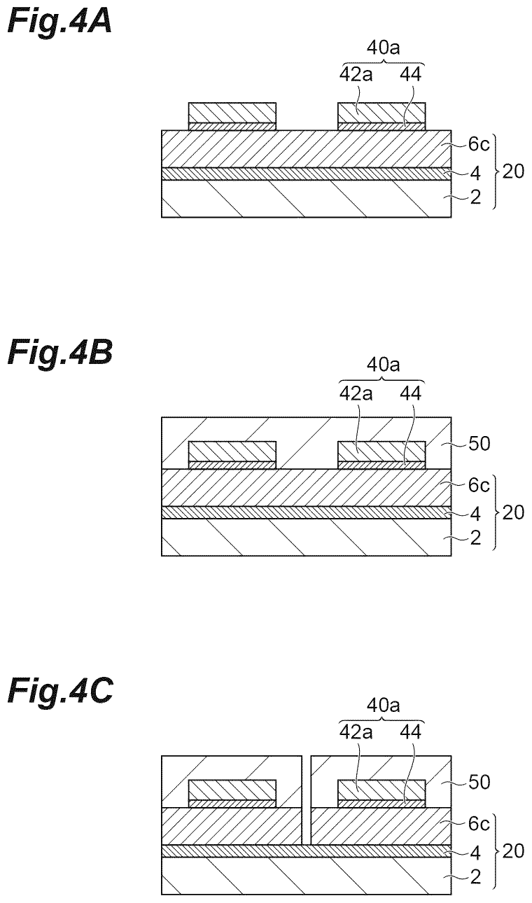

FIG. 4A, FIG. 4B, and FIG. 4C are schematic cross-sectional views illustrating one embodiment of the method for producing a semiconductor device. In the processing step, the semiconductor member 40 temporarily fixed to the support member 2 is processed. FIG. 4A illustrates an example of processing including thinning the semiconductor substrate, and a processed semiconductor member 40a has a thinned semiconductor substrate 42a and the redistribution layer 44. The processing of the semiconductor member is not limited thereto, and for example, may include thinning the semiconductor substrate, dividing (dicing) the semiconductor member, forming a through via (a through silicon via), an etching treatment, a plating reflow treatment, a sputtering treatment, or a combination thereof.

After the processing of the semiconductor member 40, as illustrated in FIG. 4B, a sealing layer 50 sealing the processed semiconductor member 40a is formed. The sealing layer 50 can be formed by using a sealing material that is commonly used to produce a semiconductor element. For example, the sealing layer 50 may be formed by a thermosetting resin composition. Examples of the thermosetting resin composition used for the sealing layer 50 include an epoxy resin such as a cresol novolac epoxy resin, a phenol novolac epoxy resin, a biphenyl diepoxy resin, and a naphthol novolac epoxy resin. The sealing layer 50 and the thermosetting resin composition for forming the sealing layer 50 may contain additives such as a filler and/or a flame retarder.

The sealing layer 50, for example, is formed by using a solid material, a liquid material, a fine-grain material, or a sealing film. In the case of using the sealing film, a compression sealing molding machine, a vacuum laminating machine, or the like is used. For example, by covering the processed semiconductor member 40a with a sealing film thermally melted with such a device in a condition of 40 to 180° C. (or 60 to 150° C.) and 0.1 to 10 MPa (or 0.5 to 8 MPa) for 0.5 to 10 minutes, it is possible to form the sealing layer 50. The thickness of the sealing film is adjusted such that the thickness of the sealing layer 50 is greater than or equal to that of the processed semiconductor member 40a. The thickness of the sealing film may be 50 to 2000 μm, 70 to 1500 μm, or 100 to 1000μ m.

After the sealing layer 50 is formed, as illustrated in FIG. 4C, the sealing layer 50 and the temporary fixing material layer 6c may be divided into a plurality of parts each including one processed semiconductor member 40a.

### (Separating Step)

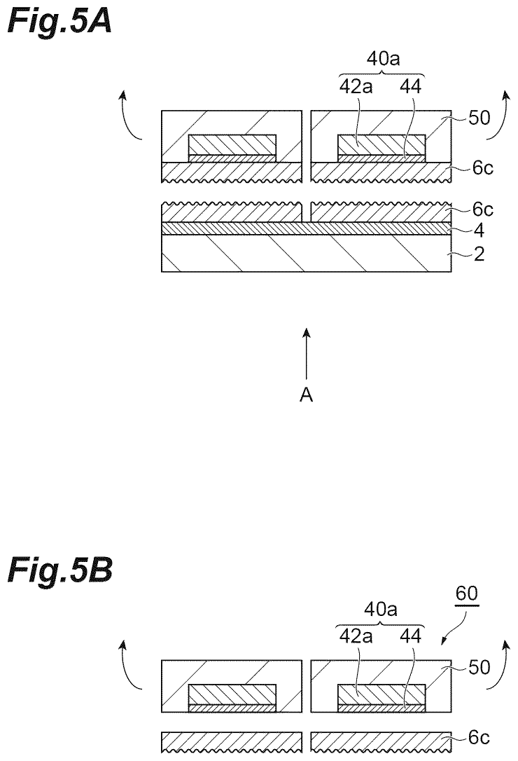

FIG. 5A and FIG. 5B are schematic cross-sectional views illustrating one embodiment of the method for producing a semiconductor device. In the separating step, the light absorption layer of the laminated body for temporary fixing is irradiated with light from the support member side to separate the semiconductor member from the support member.

As illustrated in FIG. 5A, the light absorption layer 4 of the laminated body 20 for temporary fixing is irradiated with light A from the support member 2 side to separate the processed semiconductor member 40a from the support member 2. By the irradiation of the light A, the light absorption layer 4 absorbs light to instantaneously generate heat. The generated heat, for example, may cause the melting of the temporary fixing material layer 6c, a thermal stress between the support member 2 and the processed semiconductor member 40a, and the scattering of the light absorption layer 4. Mainly due to one or two of such phenomena, cohesion peeling, interface peeling, or the like occurs, and the processed semiconductor member 40a can be easily separated from the support member 2. In order to separate the processed semiconductor member 40a from the support member 2, a stress may be slightly applied to the processed semiconductor member 40a, together with the irradiation of the light A.

The light A includes at least infrared light. The wavelength of the infrared light, in general, is 700 nm to 1 mm.

The light A in the separating step may be coherent light. The coherent light is an electromagnetic wave having a character such as high coherence, a high directional property, and high monochromaticity. The coherent light is synthesized by reinforcing in-phase light rays at the same wavelength each other, thereby tending to have high intensity. Laser light, in general, is coherent light. Examples of the laser light include YAG laser, fiber laser, semiconductor laser, helium-neon laser, argon laser, and excimer laser. The wavelength of the laser light may be 1300 nm or less. Since in a case where the wavelength is 1300 nm or less, the light absorption of the support member 2 is suppressed, and the light absorption of the metal layer 12 increases, it is possible to perform peeling at lower light irradiation energy. The coherent light may be pulsed light.

The light A in the separating step may be incoherent light. The incoherent light is light that is not coherent, and is an electromagnetic wave having a character such as no interference fringe, low coherence, and a low directional property. The incoherent light has a tendency to be attenuated as the length of a light path increases. Light such as solar light and light of a fluorescent lamp is the incoherent light. The incoherent light can also be referred to as light excluding laser light. Since the irradiation area of the incoherent light, in general, is overwhelmingly wider than that of the coherent light (that is, the laser light), it is possible to decrease the number of times for irradiation. For example, it is possible to separate a plurality of processed semiconductor members 40a by one time of irradiation. The incoherent light may include an infrared ray. The incoherent light may be pulsed light.

A light source of the light is not particularly limited, and may be a xenon lamp. The xenon lamp is a lamp using light emission due to electrical application and discharge in a light emitting tube filled with xenon gas. The xenon lamp is discharged while repeating disassociation and excitation, thereby stably having a continuous wavelength from an ultraviolet region to an infrared region. Since the xenon lamp requires a start-up time shorter than that of a lamp such as a metal halide lamp, it is possible to significantly reduce time required for the steps. In addition, since it is necessary to apply a high voltage to emit light, high heat is instantaneously generated, and the xenon lamp is also advantageous from the viewpoint that a cooling time is short, and a continuous operation is available.

An irradiation condition for the xenon lamp includes an applied voltage, a pulse width, an irradiation time, an irradiation distance (a distance between the light source and the temporary fixing material layer), irradiation energy, and the like, and can be arbitrarily set in accordance with the number of times for irradiation, or the like. From the viewpoint of reducing a damage to processed semiconductor member 40a, an irradiation condition may be set in which it is possible to separate the processed semiconductor member 40a by one time of irradiation.

A part of the temporary fixing material layer 6c may be attached as a residue onto the separated processed semiconductor member 40a. The attached residue is removed as illustrated in FIG. 5B. The attached residue, for example, may be removed by washing with a solvent, or may be peeled by peeling. The solvent is not particularly limited, and examples thereof include ethanol, methanol, toluene, xylene, acetone, methyl ethyl ketone, methyl isobutyl ketone, hexane, and the like. Only one type of the solvent may be used alone, or two or more types thereof may be used in combination. In order to remove the attached residue, the processed semiconductor member 40a may be immersed in the solvent, or washing with an ultrasonic wave may be performed. The processed semiconductor member 40a may be heated at a low temperature of approximately 100° C. or lower.

By the method exemplified as described above, it is possible to obtain a semiconductor element 60 including the processed semiconductor member 40a. By connecting the obtained semiconductor element 60 to other semiconductor chips or a substrate for mounting the semiconductor element, it is possible to produce a semiconductor device.

### EXAMPLES

Hereinafter, the present disclosure will be described in more detail by Examples (Production Examples). However, the present disclosure is not limited to such Examples (Production Examples).

### Production Examples 1 to 5: Preparation of Thermosetting Resin Film and Evaluation of Temporary Fixing Material Layer

### <Preparation of Thermosetting Resin Film>

In the preparation of a thermosetting resin film, the following components were used.

### (A) Thermoplastic Resin

(A-1a) a maleic anhydride-modified styrene/ethylene/butylene/styrene block copolymer (Tuftec M1913, manufactured by Asahi Kasei Corp., Styrene Content: 30% by mass), used as a xylene solution with a concentration of 25% by mass
(A-2a) a maleic anhydride-modified styrene/ethylene/butylene/styrene block copolymer (Tuftec M1943, manufactured by Asahi Kasei Corp., Styrene Content: 20% by mass), used as a xylene solution with a concentration of 25% by mass
(a-1b) a phenoxy resin (Phenotohto ZX-1356-2, manufactured by NIPPON STEEL Chemical & Material Co., Ltd.), used as a cyclohexanone solution with a concentration of 25% by mass

### (B) Thermosetting Resin

(B-1a) a dicyclopentadiene-type epoxy resin (HP7200H, manufactured by DIC Corporation), used as a xylene solution with a concentration of 50% by mass
(B-1b) a dicyclopentadiene-type epoxy resin (HP7200H, manufactured by DIC Corporation), used as a cyclohexanone solution with a concentration of 50% by mass

### (C) Curing Accelerator

(C-1b) an imidazole derivative (2PZ-CN, manufactured by SHIKOKU CHEMICALS CORPORATION), used as a cyclohexanone solution with a concentration of 10% by mass

### (D) Antioxidant

(D-1a) a hindered phenol derivative (AO-60, manufactured by ADEKA Corporation), used as a xylene solution with a concentration of 10% by mass
(D-1b) a hindered phenol derivative (AO-60, manufactured by ADEKA Corporation), used as a cyclohexanone solution with a concentration of 10% by mass

Materials shown in Table 1 were mixed at a ratio shown in Table 1 (Unit: parts by mass, note that a numerical value in Table 1 indicates the amount of non-volatile content) to obtain a varnish of a thermosetting resin component. The obtained varnish of the thermosetting resin component was applied to the mold-release-treated surface of a polyethylene terephthalate (PET) film (PUREX A31, manufactured by Toyobo Film Solutions Limited, Thickness: 38 μm) as a support film by using a precision coater. The coated film was dried by heating at 100° C. for 10 minutes to obtain thermosetting resin films of Production Examples 1 to 5, having a thickness of 50 μm.

### <Evaluation of Temporary Fixing Material Layer>

### 1. Push-In Depth

A push-in depth was measured by performing a push-in test with a nanoindenter (Hysitron TI980, manufactured by Bruker Japan K.K.) by a nanoindentation method using a Berkovich indenter, on the basis of ISO14577. Each of the thermosetting resin films was stuck to a glass slide by using a roll laminator, and the support film was peeled to obtain a laminated body including the glass slide, and a thermosetting resin layer provided on the glass slide. In this case, the surface of the thermosetting resin layer that is in contact with the support film is the surface of the temporary fixing material layer on a side where a semiconductor member is disposed. Next, the prepared laminated body was heated in a drier in a condition of 200° C. for 1 hour to cure the thermosetting resin component of the thermosetting resin layer, and a temporary fixing material layer containing a cured product of the thermosetting resin component is formed to obtain specimens including the temporary fixing material layers of Production Examples 1 to 5.

Subsequently, the obtained specimen was fixed to a stage of the nanoindenter, the Berkovich indenter was brought into contact with the surface of the temporary fixing material layer of the specimen, the push-in test was performed under a condition of 25° C. such that a load was increased at a loading rate of 20 μN/second for 5 seconds, retained at 100 μN for 2 seconds after the load reaches 100 μN, and decreased at an unloading rate of 20 μN/second for 5 seconds until the load was 0 mN, and a depth to which the Berkovich indenter was pushed into the temporary fixing material layer was measured by using the nanoindenter. The push-in test was performed at any 5 points, and among the obtained depths, the median value was set as the push-in depth. Results are shown in Table 1.

### (Push-In Test Condition)

Indenter: a Berkovich indenter
Loading rate: 20 μN/second
Loading time: 5 seconds (Maximum Load: 100 μN)
Retention time: 2 seconds
Unloading rate: 20 μN/second

### 2. Surface Roughness

Surface roughness was obtained by preparing the same specimen as that in “1. Push-in Depth”, and measuring the surfaces of the temporary fixing material layers of Production Examples 1 to 5 with a stylus-type surface shape measuring system (XP-2, manufactured by Ambios Technology, Inc.). The measurement was performed in the following condition. Results are shown in Table 1.

### (Measurement Condition)

Load: 4.9×10⁻⁶ N (5 mgf)
Movement rate: 0.3 mm/second
Measurement length: 30 mm

### 3. Surface Tacky Force

For a surface tacky force, the same specimen as that in “1. Push-in Depth” was prepared, and the specimen was left to stand on a stage of a probe tackiness tester (TAC-II, manufactured by RHESCA Co., LTD.) at 30° C. for 1 minute. Subsequently, for the temporary fixing material layers of Production Examples 1 to 5, the surface tacky force was obtained by using the probe tackiness tester in the following measurement condition. Results are shown in Table 1.

### (Measurement Condition)

Probe: stainless steel (SUS), a diameter of 5 mm
Push-in/peel rate: 600 mm/second
Push-in time: 1 second

### 4. 90° Peel Strength

The thermosetting resin films of Production Examples 1 to 5 were heated in a drier in a condition of 200° C. for 1 hour, and the thermosetting resin components of the thermosetting resin layers were cured to form temporary fixing material layers containing cured products of the thermosetting resin components of Production Examples 1 to 5. After that, the support film was peeled, and the surface of the temporary fixing material layer that was in contact with the support film was crimped to a silicon wafer with a vacuum laminator in a condition of temperature of 80° C./pressure of 0.5 MPa/time of 120 seconds. Subsequently, the temporary fixing material layers were cut together with the silicon wafer to have a width of 1 cm, and specimens including the temporary fixing material layers of Production Examples 1 to 5 were obtained. Subsequently, for the specimens, a peeling test was performed at a rate of 50 mm/minute by using a peeling tester (EZ-S, manufactured by SHIMADZU CORPORATION) set such that a peeling angle was 90°, and the 90° peel strength of the temporary fixing material layer with respect to the silicon wafer was measured. Results are shown in Table 1. Note that for the temporary fixing material layer of Production Example 5, which was prepared from the thermosetting resin film of Production Example 5, the temporary fixing material layer was easily peeled from the silicon wafer, which made the measurement of the 90° peel strength unavailable.

### 5. Appearance Evaluation

The surfaces of the thermosetting resin films of Production Examples 1 to 5 on a side opposite to the support film were temporarily crimped onto a 6-inch glass wafer in a condition of temperature of 80° C./pressure of 0.5 MPa/time of 120 seconds by using a vacuum laminator, and heated in a drier in a condition of 200° C. for 1 hour to obtain a plurality of laminated bodies including the temporary fixing material layers of Production Examples 1 to 5. After that, a silicon wafer was crimped onto the temporary fixing material layers of the laminated bodies in a weak condition (a condition of temperature of 150° C./pressure of 0.5 MPa/time of 120 seconds) or a strong condition (a condition of temperature of 150° C./pressure of 0.7 MPa/time of 120 seconds) to obtain specimens including the temporary fixing material layers of Production Examples 1 to 5. For the obtained specimens, the state of cohesiveness between the temporary fixing material layer and the silicon wafer was visually observed, and evaluated on the basis of the following criteria. Results are shown in Table 1.
S: after crimping in the weak condition, the floating of the silicon wafer was not observed at all.
A: after crimping in the strong condition, the floating of the silicon wafer was not observed at all.
B: after crimping in the strong condition, the floating of the silicon wafer was slightly observed.
C: after crimping in the strong condition, the silicon wafer was easily peeled.

TABLE 1

| | | Prod. | Prod. | Prod. | Prod. | Prod. |
|---|---|---|---|---|---|---|
| | | Exam. 1 | Exam. 2 | Exam. 3 | Exam. 4 | Exam. 5 |
| (A) | (A-1a) | 35 | 35 | 17.5 | 17.5 | — |
| | (A-2a) | 35 | 35 | 52.5 | 52.5 | — |
| | (a-1b) | — | — | — | — | 70 |
| (B) | (B-1a) | 30 | — | 30 | — | — |
| | (B-1b) | — | 30 | — | 30 | 30 |
| (C) | (C-1b) | 0.5 | 0.5 | 0.5 | 0.5 | 0.5 |
| (D) | (D-1a) | 0.8 | — | 0.8 | — | — |
| | (D-1b) | — | 0.8 | — | 0.8 | 0.8 |

| | | | | | | |
|---|---|---|---|---|---|---|
| Push-in depth | nm | 817 | 708 | 906 | 1022 | <500 |
| (25° C.) | | | | | | |
| Surface roughness | nm | 21 | 4 | 11 | 2 | >100 |
| Surface tacky | N | 4.0 × 10⁻² | 3.6 × 10⁻² | 5.4 × 10⁻² | 5.2 × 10⁻² | 9.8 × 10⁻⁴ |
| force (30° C.) | | | | | | |
| 90° Peel strength | N/cm | 0.20 | 0.10 | 0.25 | 0.20 | — |

| | | | | | |
|---|---|---|---|---|---|
| Appearance evaluation | A | B | S | S | C |

As shown in Table 1, for the temporary fixing material layers of Production Examples 1 to 4 prepared from the thermosetting resin films of Production Examples 1 to 4 in which the push-in depth measured in a predetermined condition was 600 nm or more, the measurement of the 90° peel strength with respect to the silicon wafer was available, and a sufficient bonding adhesive strength with the silicon wafer was attained. On the other hand, the temporary fixing material layer of Production Example 5 prepared from the thermosetting resin film of Production Example 5 in which the push-in depth did not satisfy the condition was easily peeled from the silicon wafer, which made the measurement of the 90° peel strength unavailable. From such results, it was indicated that the method for producing a semiconductor device of the present disclosure is capable of sufficiently fixing the semiconductor member and the support member.

### INDUSTRIAL APPLICABILITY

According to the present disclosure, the method for producing a semiconductor device including processing the semiconductor member temporarily fixed to the support member is provided, in which it is possible to sufficiently fix the semiconductor member and the support member. In addition, in the method for producing a semiconductor device of several modes, there is a tendency that it is possible to sufficiently reduce the peeling residue after separating the semiconductor member from the support member. In addition, according to the present disclosure, the laminated body for temporary fixing used for such a method for producing a semiconductor device is provided.

### REFERENCE SIGNS LIST

2: support member, 4: light absorption layer, 6: thermosetting resin layer, 6c: temporary fixing material layer, 10: laminated precursor, 20: laminated body for temporary fixing, 30: laminated body, 40: semiconductor member, 40a: processed semiconductor member, 42: semiconductor substrate, 42a: thinned semiconductor substrate, 44: redistribution layer, 50: sealing layer, 60: semiconductor element.

1. A method for producing a semiconductor device, comprising:
preparing a laminated body for temporary fixing comprising a support member, a light absorption layer, and a temporary fixing material layer comprising a cured product of a thermosetting resin component in this order from the support member;
temporarily fixing a semiconductor member to the support member via the light absorption layer and the temporary fixing material layer;
processing the semiconductor member temporarily fixed to the support member; and
irradiating the light absorption layer of the laminated body for temporary fixing with light from the support member side to separate the semiconductor member from the support member,
wherein a push-in depth when on a surface of the temporary fixing material layer on a side in which the semiconductor member is disposed, a nanoindentation method using a Berkovich indenter is performed under a condition of 25° C. such that a load is increased at a loading rate of 20 μN/second for 5 seconds, retained at 100 μN for 2 seconds after the load reaches 100 μN, and decreased at an unloading rate of 20 μN/second for 5 seconds until the load is 0 mN is 600 nm or more.

2. The method for producing a semiconductor device according to claim 1,
wherein surface roughness in the surface of the temporary fixing material layer on a side in which the semiconductor member is disposed is 50 nm or less.

3. The method for producing a semiconductor device according to claim 1,
wherein a surface tacky force at 30° C. in the surface of the temporary fixing material layer on a side in which the semiconductor member is disposed is 9.8×10⁻³ N or more.

4. The method for producing a semiconductor device according to claim 1,
wherein the thermosetting resin component comprises a thermoplastic resin and a thermosetting resin, and
the thermoplastic resin comprises a hydrocarbon resin.

5. The method for producing a semiconductor device according to claim 4,
wherein the hydrocarbon resin comprises a hydrocarbon resin having a monomer unit derived from styrene.

6. A laminated body for temporary fixing used to temporarily fix a semiconductor member and a support member, comprising:
a support member;
a light absorption layer; and
a temporary fixing material layer comprising a cured product of a thermosetting resin component in this order from the support member,
wherein a push-in depth when on a surface of the temporary fixing material layer on a side in which the semiconductor member is disposed, a nanoindentation method using a Berkovich indenter is performed under a condition of 25° C. such that a load is increased at a loading rate of 20 μN/second for 5 seconds, retained at 100 μN for 2 seconds after the load reaches 100 μN, and decreased at an unloading rate of 20 μN/second for 5 seconds until the load is 0 mN is 600 nm or more.

7. The laminated body for temporary fixing according to claim 6,
wherein surface roughness in the surface of the temporary fixing material layer on a side in which the semiconductor member is disposed is 50 nm or less.

8. The laminated body for temporary fixing according to claim 6,
wherein a surface tacky force at 30° C. in the surface of the temporary fixing material layer on a side in which the semiconductor member is disposed is 9.8×10⁻³ N or more.

9. The laminated body for temporary fixing according to claim 6,
wherein the thermosetting resin component comprises a thermoplastic resin and a thermosetting resin, and
the thermoplastic resin comprises a hydrocarbon resin.

10. The laminated body for temporary fixing according to claim 9,
wherein the hydrocarbon resin comprises a hydrocarbon resin having a monomer unit derived from styrene.

11. The method for producing a semiconductor device according to claim 2,
wherein the thermosetting resin component comprises a thermoplastic resin and a thermosetting resin, and
the thermoplastic resin comprises a hydrocarbon resin.

12. The method for producing a semiconductor device according to claim 3,
wherein the thermosetting resin component comprises a thermoplastic resin and a thermosetting resin, and
the thermoplastic resin comprises a hydrocarbon resin.

13. The laminated body for temporary fixing according to claim 7,
wherein the thermosetting resin component comprises a thermoplastic resin and a thermosetting resin, and
the thermoplastic resin comprises a hydrocarbon resin.

14. The laminated body for temporary fixing according to claim 8,
wherein the thermosetting resin component comprises a thermoplastic resin and a thermosetting resin, and
the thermoplastic resin comprises a hydrocarbon resin.
